(19) United States
(12) Patent Application Publication
(10) Pub. No.: US 2008/0191360 A1
(43) Pub. Date: Aug. 14, 2008

(54) Adhesive Strip Conductor on an Insulating Layer

(76) Inventors: Karl Weidner, Munchen (DE); Robert Weinke, Munchen (DE); Hans Wulkesch, Munchen (DE)

Correspondence Address: HARNESS, DICKEY & PIERCE, P.L.C., P.O.BOX 8910, RESTON, VA, 20195, US

(21) Appl. No.: 11/884,231

(22) PCT Filed: Dec. 22, 2005
(86) PCT No.: PCT/EP05/57090

§ 371 Date: Aug. 13, 2007

(30) Foreign Application Priority Data
Feb. 14, 2005 (DE) 10 2005 006 638.0

(51) Int. Cl. H01L 23/48; H01L 21/44

(52) U.S. Cl. 257/775; 438/674; 257/E23.01; 257/E21.476

(57) ABSTRACT

A device is disclosed with at least one electrically insulating layer on which at least one conductor structure made of electrically conductive material is placed. In at least one embodiment, the conductor structure on the side facing the insulating layer has at least one elevation that is accommodated in at least one recess in the insulating layer.

### PRIORITY STATEMENT

This application is the national phase under 35 U.S.C. § 371 of PCT International Application No. PCT/EP2005/057090 which has an International filing date of Dec. 22, 2005, which designated the United States of America and which claims priority on German Patent Application number 10 2005 006 638.0 filed Feb. 14, 2005, the entire contents of which are hereby incorporated herein by reference.

### FIELD

At least one embodiment of the present invention generally relates to a device and/or a method.

### BACKGROUND

Due to the different thermal expansion properties of the materials involved, that is the substrate, the layer of electrically insulating material and the strip conductors become detached and/or are even interrupted or destroyed under stress conditions, as a result of changes in temperature. This applies in particular to the Cu-structures in WO 2003030247-A2 produced in conjunction with a so-called SiPLIT (Siemens Planar Interconnect Technology) process, which can become detached under stress conditions due to temperature cycles.

The detachment of strip conductor structures is conventionally avoided by adapting the coefficients of thermal expansion of the materials involved. This solution is complex. Materials with adapted coefficients of expansion are not available in every case.

### SUMMARY

At least one embodiment of the present invention produces conductor structures on semi-conductor elements or substrates that are insensitive to thermomechanical stresses in order effectively to avoid the interruption of electrical connections in a simple manner.

According to at least one embodiment of the present invention, devices are developed in such a way that a conductor structure to be attached includes, on the side facing an insulating layer, at least one elevation or material elevation for accommodation in at least one recess or material recess in the insulating layer. The elevation of the conductor structure is accommodated in the recess in the insulating layer. Conductor structure means any type of arrangement providing an electrical connection, for example in the form of a strip conductor or as a flat shape. A plurality of conductor structures can be created by electrically insulating layers or dielectrics arranged separately next to each other and/or one on top of the other. In particular, it should be possible to produce multilayer SiPLIT structures. Particularly suitable as the material for the conductor structures is copper Cu. Other metals can also be used. The provision of an elevation from the conductor structure and the accommodation thereof in an associated recess in the dielectric layer creates a mechanical connection between the conductor structure and the insulating layer in a simple and effective way. The elevation is encompassed by the recess and fixed in this way or held by friction. The recess can be provided as a “dead end” or as passageway through the insulating layer (dielectric). For example, a blind hole shape can suffice as the mechanical connection. It is also possible to glue the elevation to the recess.

According to an advantageous embodiment, the shape of the recess is matched to the shape of the elevation in such a way that a positive engagement is created. This means that the elevation lies tightly against the recess. Therefore, the recess is a sort of negative shape of the elevation. This enables, for example, a press fit to be created or at least a friction force between the elevation and the recess, which is sufficient for the mechanical fixing of the conductor structure on the dielectric.

According to a further advantageous embodiment, the shape of the recess is matched to the shape of the elevation in such a way that anchoring of the elevation in the recess is created. This means that the elevation can become hooked in the recess and is therefore anchored therein. Alternatively or cumulatively to the mechanical connection by means of friction, the matching of the shape of the recess and elevation can create a mechanical hooking in one another. This can be achieved, for example, by means of a snap connector. Other anchoring mechanisms are also conceivable. If the recess is designed as a passageway, the elevation of the conductor structure can, for example, be hooked or anchored on the edge of the facing-away side of the insulating layer.

According to a further advantageous embodiment, the elevation is embodied as a bar and the recess as a channel. The bar and channel can take any course along the connecting surface between the conductor structure and the insulating layer. One example is a circular shape. This enables the mechanical connection to be achieved over a large area of the conductor structure which is to be connected by a mechanical device/method to the insulating layer. The conductor structure can, for example, be advantageously embodied as a flat surface.

According to a further advantageous embodiment, the elevation is designed as a type of plug and the recess as a type of socket, for example in a blind hole shape. In this way, the elevation can be mechanically fixed in a simple way by accommodation in the recess. With an increasing number of, in particular plug-like or pin-like elevations accommodated by recesses, the connecting force between the conductor structure and insulating layer can be increased.

According to a further advantageous embodiment, an elevation has the shape of a pin, a cylinder, a cone, a prong, a pronged structure and/or a screw and the recess has the associated negative shape in each case. Similarly, the elevation can have corresponding hollow shapes such as for example hollow cylinders or hollow cones. If, for example, it is wished to create improved adhesion of different SiPLIT—layers, in particular a dowelled joint is suitable. To achieve this, a dowel is positioned in the recess. The conductor structure only has an opening in the corresponding place. Through this opening, a screw is twisted into the dowel in the recess. Thus, the elevation of the conductor structure is created by a unit separated therefrom in the form of a screw. After the screwing, the screw can be considered to be an elevation mechanically connected to the conductor structure.

According to a further advantageous embodiment, the electrically insulating layer is arranged on a substrate. In this way, the mechanical stability of the device is substantially increased. On the substrate, semi-conductor components, in particular power semi-conductor components can be arranged between the insulating layer and the substrate. Contact surfaces for electrical contacting can be provided on the substrate and/or the semi-conductor component.

According to a further advantageous embodiment, the conductor structure is in electrical contact by way of the elevation with at least one contact zone on the substrate and/or with at least one contact zone on at least one semi-conductor chip arranged on the surface of the substrate, with the recess being designed as a passageway for the elevation to the contact zone. In this way, the conductor structure is in electrical contact in particular with a semi-conductor chip. The recess preferably penetrates the insulating layer.

According to a further advantageous embodiment, the conductor structure is in electrical contact through at least one window in a planar way through the electrically insulating layer with at least one contact surface on the substrate and/or with at least one contact surface on at least one semi-conductor chip arranged on the surface of the substrate. This electrical contacting corresponds to the contacting according to aforementioned SiPLIT technology.

According to one example embodiment, a method for creating one of the devices described above is provided with the steps: creation of at least one layer made of electrically insulating material with at least one material recess and application of a conductor structure to the layer and thereby filling of the material recess with the conductor material of the conductor structure.

According to an advantageous embodiment, the at least one conductor structure with at least one elevation for accommodation in the material recess can, before application on the layer made of electrically insulating material (insulating layer), be first created as an independent unit separate from the layer made of electrically insulating material. This unit, in particular the elevation, is then for example coupled mechanically to the insulating layer by pressing in the insulating layer or in the recess and fixed thereto.

According to a further advantageous embodiment, the application of the conductor structure can take place by way of physical, chemical and/or electrochemical metallization. Possible variants are for example spraying, sputtering and/or vapor deposition. Galvanic reinforcement is also possible.

According to further embodiments, the filling of the recess with the conductor material of the conductor structure can be performed completely or with a hollow shape. In the latter case of partial filling, the elevation can have the shape of a sleeve or a hollow cylinder surrounding a hollow space. Hereby, the conductor material in particular only lies on the wall of the recess. Any hollow shapes of the material elevation can be created in connection with the associated material recess.

According to a further advantageous embodiment, the layer made of electrically insulating material is applied to the surface of a substrate.

According to a further advantageous embodiment, the recess is created as a passageway for the elevation to at least one contact zone on the substrate and/or to at least one contact zone on at least one semi-conductor chip arranged on the surface of the substrate and electrical contacting of the conductor structure with the contact zone achieved by way of the elevation. This can be achieved for example by soldering.

According to a further advantageous embodiment, at least one window is created in the electrically insulating layer as a passageway for the conductor structure to at least one contact zone on the substrate and/or to at least one contact zone on at least one semi-conductor chip arranged on the surface of the substrate and planar electrical contacting of the conductor structure through the window with the contact zone.

According to a further advantageous embodiment, the recess and/or the window is/are created by way of lasers, plasma etching, chemical etching and/or photographically.

### BRIEF DESCRIPTION OF THE DRAWINGS

The present invention is described in more detail with reference to an example of an example embodiment in conjunction with FIG. 1, which shows

FIG. 1 an example embodiment of an embodiment of a mechanical connection of a strip conductor with a dielectric.

FIG. 1 shows a cross-section of a substrate 1 on which is arranged an electrically insulating layer 3. The layer 3 can, for example, be laminated onto the substrate 2. Other connection methods are also possible. On the side of the dielectric 3 facing away from the substrate 1, a conductor structure 5 is created in the form of a strip conductor and in particular in the form of a SiPLIT strip conductor. Reference number 7 designates an elevation of the strip conductor 5 on the side facing the insulating layer 3. This material elevation 7 is cylindrical, cone-shaped and prong-shaped. Other shapes are also possible. The electrically insulating layer 3 has material recesses 9 corresponding to the elevations 7 in the form of a hollow cylinder, a hollow cone and a hollow prong shape. FIG. 1 shows a positive engagement between the elevation 7 and recess 9. In addition, the right-hand mechanical connecting structure shows that the elevation 7 is hooked with the recess. In this way, a layer sequence that may be exposed to thermomechanical forces is created which avoids the detachment or interruption of the conductor structure 5 due to different coefficients of expansion of the materials. Fixing by means of elevations 7 and recesses 9 causes the strip conductor 5 to remain in reliable mechanical connection with the electrically insulating layer 3 despite thermally induced deformations. In addition, these mechanical connecting points can be used for electrical contacting of the conductor structure 5 with further electrical contact zones. Suitable openings are created in the dielectric layer 3 for the firm connection of the strip conductor 5 and for electrical contacting. Openings or material recesses 9 can, for example, be created as blind hole openings or as passage openings.

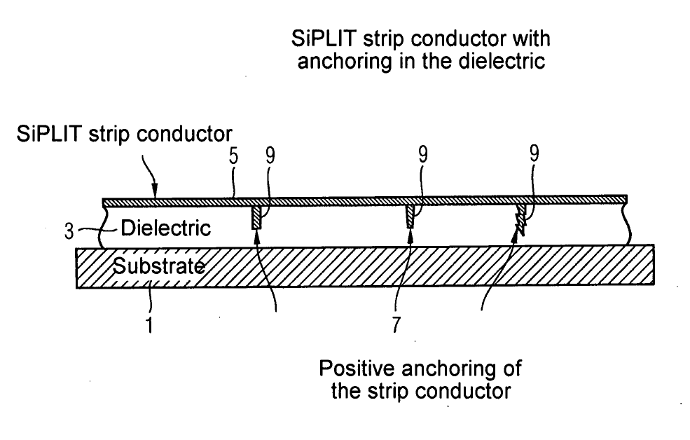

The described connecting mechanism in particular permits improved adhesion of the different SiPLIT layers to each other by way of adapted dowel or snap connectors.

The openings or material recesses 9 can be created by way of lasers, photography, plasma etching or chemical etching.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A device comprising:
at least one electrically insulating layers; and
at least one conductor structure, made of electrically conductive material, applied on the at least one electrically insulating layer, the at least one conductor structure, on a side facing the at least one electrically insulating layer, includes at least one of
an elevation for accommodation in at least one recess in the insulating layer,
the elevation including a shape of at least one of a cone, a hollow cone and a screw and the recess including an associated negative shape in each case, and
a dowel connection, formed between the at least one conductor structure and the at least one electrically insulating layer.

2. The device as claimed in claim 1, wherein a shape of the recess is matched to a shape of the elevation to create a positive engagement.

3. The device as claimed in claim 1, wherein a shape of the recess is matched to a shape of the elevation in such a way that an anchoring of the elevation in the recess is obtained.

4. The device as claimed in claim 1, wherein the elevation is embodied as a bar and the recess is embodied as a channel.

5. The device as claimed in claim 1, wherein the elevation is embodied as a type of plug and the recess is embodied as a type of socket.

6. The device as claimed in claim 1, wherein
the electrically insulating layer is arranged on a substrate.

7. The device as claimed in claim 6, wherein, by way of the elevation, the conductor structure is in electric contract with at least one of at least one contact zone on the substrate and at least one contact zone on at least one semi-conductor arranged on the surface of the substrate, with the recess being embodied as a passageway between the elevation and the contact zone.

8. The device as claimed in claim 6, wherein the conductor structure is in planar electrical contact through at least one window in the electrically insulating layer at least one of with at least one contact surface on the substrate and with at least one contact surface on at least one semi-conductor chip arranged on the surface of the substrate.

9. A method for creating a device including at least one electrically insulating layer; and at least one conductor structure, made of electrically conductive material, applied on the at least one electrically insulating layer, the at least one conductor structure, on a side facing the at least one electrically insulating layer, includes at least one of an elevation for accommodation in at least one recess in the insulating layer, the elevation including a shape of at least one of a cone, a hollow cone and a screw and the recess including an associated negative shape in each case, and a dowel connection, formed between the at least one conductor structure and the at least one electrically insulating layer, the method comprising:
creating at least one layer of electrically insulating material with at least one of at least one recess and at least one window;
applying at least one conductor structure to the layer of electrically insulating material and thereby filling the at least one of the recess and window with conductor material of the conductor structure, the at least one of
the recess and the window being created by way of at least one of plasma etching and chemical etching.

10. The method as claimed in claim 9, further comprising:
separately creating, before the applying, the at least one conductor structure with at least one elevation for accommodation in the at least one of recess and window.

11. The method as claimed in claim 9, wherein the applying of the at least one conductor structure is done by way of at least one of physical, chemical and electrochemical metallization.

12. The method as claimed in claim 9, wherein—the filling of at least one of the recess and the window with the conductor material of the conductor structure takes place at least one of completely and with a hollow shape.

13. The method as claimed in claim 9, further comprising:
applying the layer made of electrically insulating material to the surface of a substrate.

14. The method as claimed in claim 13, further comprising:
creating the recess as a passageway for the elevation to at least one of at least one contact zone on the substrate and at least one contact zone on at least one semi-conductor chip arranged on the surface of the substrates; and
electrically contacting between the conductor structure and the contact zone by way of the elevation.

15. The method as claimed in claim 13, further comprising:
creating the at least one window in the electrically insulating layer as a passageway for the conductor structure to at least one of at least one contact zone on the substrate and at least one contact zone on at least one semi-conductor chip arranged on the surface of the substrate; and
planar electrically contacting the conductor structure with the contact zone through the window.

16.-17. (canceled)

18. The device as claimed in claim 2, wherein the elevation is embodied as a bar and the recess is embodied as a channel.

19. The device as claimed in claim 3, wherein the elevation is embodied as a bar and the recess is embodied as a channel.

20. The device as claimed in claim 2, wherein the elevation is embodied as a type of plug and the recess is embodied as a type of socket.

21. The device as claimed in claim 3, wherein the elevation is embodied as a type of plug and the recess is embodied as a type of socket.

22. The device as claimed in claim 7, wherein the conductor structure is in planar electrical contact through at least one window in the electrically insulating layer at least one of with at least one contact surface on the substrate and with at least one contact surface on at least one semi-conductor chip arranged on the surface of the substrate.

23. The method as claimed in claim 14, further comprising:
creating the at least one window in the electrically insulating layer as a passageway for the conductor structure to at least one of at least one contact zone on the substrate and at least one contact zone on at least one semi-conductor chip arranged on the surface of the substrate; and
planar electrically contacting the conductor structure with the contact zone through the window.
